(19) United States
(12) Patent Application Publication
(10) Pub. No.: US 2010/0025229 A1
(43) Pub. Date: Feb. 4, 2010

(54) Apparatus and method for sputtering target debris reduction

(75) Inventor: Greg Miller, DeWitt, IA (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 12/219,944

(22) Filed: Jul. 30, 2008

(51) Int. Cl. C23C 14/35

(52) U.S. Cl. 204/192.12; 204/298.19

(57) ABSTRACT

Certain example embodiments relate to techniques for reducing the amount of debris being formed on the surface of planar sputtering targets. More particularly, a coating may be applied to the sputtering material in areas where sputtering substantially does not occur (typically inside and outside of a racetrack) in certain example embodiments. The coating optionally may be cured. In certain example embodiments, the coating may be include inorganic materials or materials that resist decomposition in a severely oxidizing environment, and/or are electrically non-conductive materials. For example, the coating may be a cured-form sol-gel comprising, for example, silicon oxide, titanium oxide, and/or the like. The coating substantially encapsulates the target material where sputtering substantially does not occur, thus reducing the amount of debris that is created during sputter coating.

### FIELD OF THE INVENTION

Certain example embodiments of this invention relate to sputtering targets. More particularly, certain example embodiments of this invention relate to techniques for reducing the amount of debris being formed on the surface of planar sputtering targets. In certain example embodiments, a coating (e.g., a sol-gel based coating) is applied to areas of planar targets that are subject to substantially uninterrupted surface oxidation (e.g., inside or outside of the “racetrack” of sputtering targets) and then cured to substantially encapsulate such areas, thereby reducing the likelihood of oxidation occurring on or proximate to such encapsulated areas and thus also reducing the amount of debris that otherwise would be formed by such oxidation. In certain example embodiments, the coating may include silicon oxide, titanium oxide, and/or the like.

### BACKGROUND AND SUMMARY OF EXAMPLE EMBODIMENTS OF THE INVENTION

The use of sputtering in order to deposit coatings on substrates is known in the art. For example, and without limitation, see U.S. Pat. Nos. 5,922,176; 5,403,458; 5,317,006; 5,527,439; 5,591,314; 5,262,032; and 5,284,564, the entire contents of each of which are hereby incorporated herein by reference. Briefly, sputter coating is a thin film coating process that involves the transport of almost any material from a target to a substrate of almost any other material. The ejection of the target material is accomplished by bombarding the surface of the target with gas ions accelerated by a high voltage. Particles are ejected from the target as a result of momentum transfer between the accelerated gas ions and the target. Upon ejection, the target particles traverse the sputtering chamber and are subsequently deposited on a substrate as a thin film.

Sputtering processes typically utilize an enclosed chamber confining a sputtering gas, a target electrically connected to a cathode, a substrate, and a chamber which itself may serve as the electrical anode. A power supply typical is connected such that the negative terminal of the power supply is connected to the cathode and the positive terminal is connected to the chamber walls. In operation, a sputtering gas plasma is formed and maintained within the chamber near the surface of the sputtering target. By electrically connecting the target to the cathode of the sputtering power supply and creating a negative surface charge on the target, electrons are emitted from the target. These electrons collide with atoms of the sputtering gas, thereby stripping away electrons from the gas molecules and creating positively charged ions. The resulting collection of positively charged ions together with electrons and neutral atoms is referred to generally as a sputtering gas plasma. The positively charged ions are accelerated toward the target material by the electrical potential between the sputtering gas plasma and the target and bombard the surface of the target material. As ions bombard the target, molecules of target material are ejected from the target surface and coat the substrate.

One known technique for enhancing conventional sputtering processes involves arranging magnets behind or near the target to influence the path taken by electrons within the sputtering chamber, thereby increasing the frequency of collisions with sputtering gas atoms or molecules. Additional collisions create additional ions, thus further sustaining the sputtering gas plasma. An apparatus utilizing this enhanced form of sputtering by means of strategically located magnets generally is referred to as a magnetron system.

Unfortunately, conventional sputtering techniques suffer from several disadvantages. For example, one drawback of conventional sputtering techniques relates to the creation of sputtered regions and non-sputtered regions on sputtering targets. For example, in DC magnetron sputtering processes, sputtered regions arise from the particular arrangement of magnets near the magnetron sputtering cathode and target. For a planar target that has been at least partially sputtered, a sputtered region typically appears as an oval or racetrack-shaped depression on the target surface. The rest of the target surface where sputtering does not substantially occur may be thought of as being a non-sputtered region(s). Additionally, it is noted that for a non-rotating cylindrical magnetron target, the sputtered region also typically would appear as an oval or racetrack-shaped depression on the target surface, depending upon the particular arrangement of magnets near the target.

As reactive sputtering takes place, a thin layer of the reacted target material (usually non-conductive) often builds up in the non-sputtered regions of the target, as well as upon other exposed components inside the chamber. For example, DC planar sputtering targets used for the deposition of a nichrome (e.g., NiCr) alloy in a reactive (e.g., oxidizing) environment have been found to exhibit surface oxidation in regions exposed to the oxidic plasma. This surface oxidation leads to a build-up of NiCrOx debris that eventually flakes off of the surface and falls onto the chamber floor and/or onto the product being coated. The inventor of the instant application has observed that the areas of the planar target with the most significant amount of debris include areas of the nichrome target, both inside and outside of the magnetic racetrack. For example, FIG. 1 is a partial top perspective view of a conventional sputtering target 10 having debris located inside (2) and outside (4) of a racetrack 6.

This debris may be formed by the surface oxidation of the nichrome target homogenously, but areas on the racetrack generally are purged of debris by virtue of the sputtering process itself. That is, debris typically is ejected from such areas during the sputtering itself. However, areas that are not a part of the racetrack (but are inside of the highly oxidizing plasma) are left to oxidize substantially continuously throughout the production campaign.

To counteract the formation of debris, current techniques rely on at least temporarily suspending the sputtering campaign (e.g., turning off the sputtering targets and allowing the environment to reach a safe level) during which time the debris may be removed. For example, current methods of debris treatment include removal of debris by physical vibrations, burn-ins that either oxidize the debris causing it to become more fragile and flake off, and/or coating the debris with a metal layer to encapsulate it. Unfortunately, such current techniques require the sputtering campaign to be at least temporarily halted, thereby taking up time and costing money. In addition, such techniques involve an approach that reacts to a problem rather than an approach that reduces the likelihood of the problem from occurring in the first place.

Thus, it will be appreciated that there is a need in the art for techniques that address the problem by reducing the amount of debris that forms in the first place. As such, certain example embodiments relate to techniques that reduce the amount of debris being formed on the surface of planar sputtering targets.

One illustrative aspect of certain example embodiments relates to the application of a coating to the sputtering material in areas where sputtering substantially does not occur (typically inside and outside of a racetrack). The coating optionally may be cured in certain example embodiments. In certain example embodiments, the coating may be comprise inorganic materials or materials that resist decomposition in a severely oxidizing environment, and/or are electrically non-conductive materials. For example, the coating may be a cured-form sol-gel comprising, for example, silicon oxide, titanium oxide, and/or the like.

In certain example embodiments of this invention, a magnetron sputtering apparatus for sputter coating an article in a reactive environment is provided. A vacuum chamber is provided. One or more magnets are arranged to facilitate the sputter coating of the article. A sputtering target is located in the vacuum chamber. The sputtering target has a target material located thereon. An encapsulating coating is formed, directly or indirectly, on the target material at one or more first areas thereof where the target material substantially is not used in the sputter coating of the article. The encapsulating coating substantially isolates the target material at the one or more first areas from the reactive environment of the sputtering apparatus.

In certain example embodiments, a method for reducing an amount of debris created during sputtering is provided. There is provided a magnetron sputtering apparatus configured to generate a reactive environment used in sputter coating an article, the magnetron sputtering apparatus comprising a vacuum chamber, one or more magnets arranged to facilitate the sputter coating of the article, a sputtering target having target material located thereon and being located in the vacuum chamber. An encapsulating coating is formed, directly or indirectly, on the target material at one or more first areas thereof where the target material substantially is not used in the sputter coating of the article. The encapsulating coating substantially isolates the target material at the one or more first areas from the reactive environment of the sputtering apparatus.

In certain example embodiments, a magnetron sputtering apparatus for sputter coating an article in an oxidizing environment is provided. A vacuum chamber is provided. One or more magnets are arranged to facilitate the sputter coating of the article. A DC planar sputtering target is located in the vacuum chamber. The sputtering target has a target material located thereon. A cathode is connected to the sputtering target. An encapsulating coating is formed, directly or indirectly, on the target material at one or more first areas thereof where the target material substantially is not used in the sputter coating of the article. The encapsulating coating substantially isolates the target material at the one or more first areas from the oxidizing environment of the sputtering apparatus. The encapsulating coating includes inorganic materials or materials that resist decomposition in the oxidizing environment, and is substantially electrically non-conductive. The encapsulating coating is formed on the target material such that at least some of the target material is exposed to the oxidizing environment in a racetrack-like shape of the target material that corresponds to at least a second area of the target material where the target material substantially is used in the sputter coating of the article. The encapsulating coating reduces an amount of debris that otherwise would be formed by oxidation of the target material in the one or more first areas by at least about 50%.

The features, aspects, advantages, and example embodiments described herein may be combined to realize yet further embodiments.

### BRIEF DESCRIPTION OF THE DRAWINGS

These and other features and advantages will be better and more completely understood by reference to the following detailed description of exemplary illustrative embodiments in conjunction with the drawings, of which:

FIG. 1 is a partial top perspective view of a conventional sputtering target having debris located inside and outside of its racetrack;

FIG. 2 is a simplified schematic illustration of a conventional reactive DC magnetron sputtering apparatus and target;

FIG. 3 is a top plan view of a conventional, planar sputtering target before sputtering;

FIG. 4 is a cross section of the sputtering target of FIG. 3 before sputtering;

FIG. 5 is a top plan view of a planar sputtering target in accordance with an example embodiment;

FIG. 6 is a cross section of the sputtering target of FIG. 5 in accordance with an example embodiment; and

FIG. 7a shows an example result of a U.S. Mint quarter having been treated with an oxidation barrier and cured according to an example embodiment and then fed through a simulated oxidation environment;

FIG. 7b shows an example result of a U.S. Mint quarter having been treated with an oxidation barrier according to an example embodiment and then fed through a simulated oxidation environment; and

FIG. 7c shows an example result of a U.S. Mint quarter having been fed through a simulated oxidation environment.

### DETAILED DESCRIPTION OF EXAMPLE EMBODIMENTS OF THE INVENTION

Certain example embodiments relate to techniques for reducing the amount of debris being formed on the surface of planar sputtering targets. More particularly, a coating may be applied to the sputtering material in areas where sputtering substantially does not occur (typically inside and outside of a racetrack) in certain example embodiments. The coating optionally may be cured. In certain example embodiments, the coating may be include inorganic materials or materials that resist decomposition in a severely oxidizing environment, and/or are electrically non-conductive materials. For example, the coating may be a cured-form sol-gel comprising, for example, silicon oxide, titanium oxide, and/or the like. The coating substantially encapsulates the target material where sputtering substantially does not occur, thus reducing the amount of debris that is created during sputter coating.

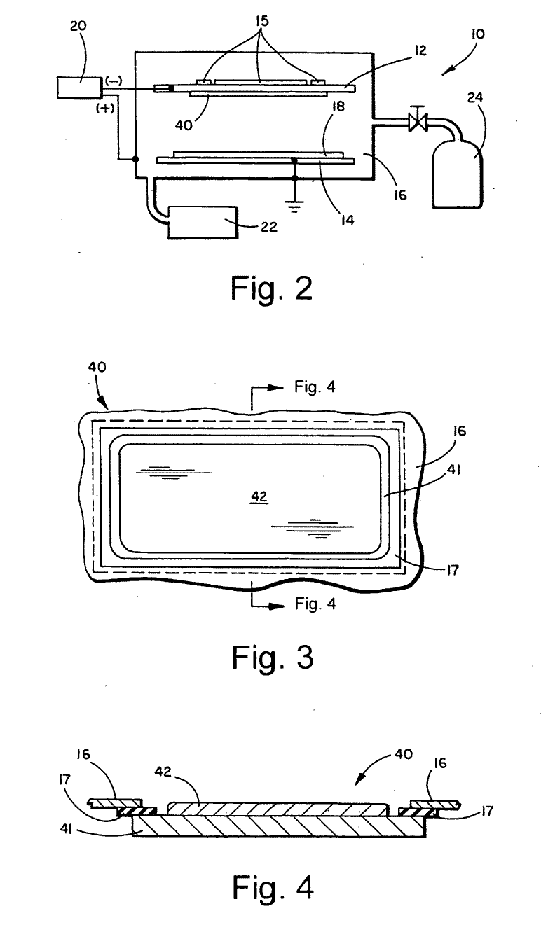

Referring now more particularly to the accompanying drawings in which like reference numerals indicate like parts throughout the several views, FIG. 2 is a simplified schematic illustration of a conventional reactive DC magnetron sputtering apparatus and target. Apparatus 10 typically includes a sputtering chamber 16, a vacuum means 22 to evacuate the chamber, a sputtering target such as a planar target 40 (as illustrated in FIGS. 3-4, for example), one or more magnets 15, a supply of sputtering gas 24, a power supply 20 having a positive terminal and a negative terminal, and means 14 to support and/or transport the substrate in the deposition region of the chamber. The target typically is electrically connected to cathode 12. Cathode 12 typically is electrically connected to the negative terminal of power supply 20. The sputtering chamber 16 itself sometimes is the electrical anode. Alternately, a separate anode element may be included inside the sputtering chamber and may be connected to its own power supply so as to be at some set potential other than ground with respect to cathode 12. Typically, the sputtering chamber 16 is at ground potential and, in some example instances, the sputtering chamber 16 may be connected to the positive terminal of the power supply. Usually, the target is at the most negative potential of any of the components of the sputtering apparatus (besides the negative terminal of the power supply). It will be appreciated that various electrical connections may be made between the power supply 20 and the various components of the sputtering apparatus 10.

Once the sputtering chamber 16 has been evacuated to the desired vacuum level by vacuum means 22, a sputtering gas 24 is introduced into chamber 16. In certain example sputtering processes, the sputtering gas 24 may be an inert gas such as argon, neon, etc. Other forms of sputtering processes known as reactive sputtering may use reactive non-inert gases such as oxygen or nitrogen. In addition, some sputtering operations may utilize a mixture of one or more inert gases and/or non-inert gases.

The sputtering target provides the material which is to be deposited onto the substrate. The size, shape, and construction of the target may vary depending upon the material and the size and shape of the substrate. A typical planar sputtering target 40 before sputtering is shown in FIGS. 3-4. The planar sputtering target 40 comprises an electrically conducting backing plate 41 and a layer of electrically conducting target material 42 deposited thereon. An electrical insulator 17 may be employed to cover any exposed region of backing member 41 or other underlying surface. Typically, the chamber walls 16 will abut insulator 17 and extend up to, but not contact, the target material 42. Backing member 41 is not necessary for all target materials (e.g., such as those that are inherently rigid or of sufficient thickness). Thus, in such instances, the target material itself may also serve as the backing member.

As noted above, after the initial onset of sputtering, regions of sputtering and non-sputtering will appear on the surface of target material 42. The outline of sputtered region will vary from one magnetron sputtering apparatus to another, as such outlines are influenced, among other things, by the particular arrangement of magnets near the cathode and target. However, the sputtered region generally will have a substantially ovular or racetrack pattern.

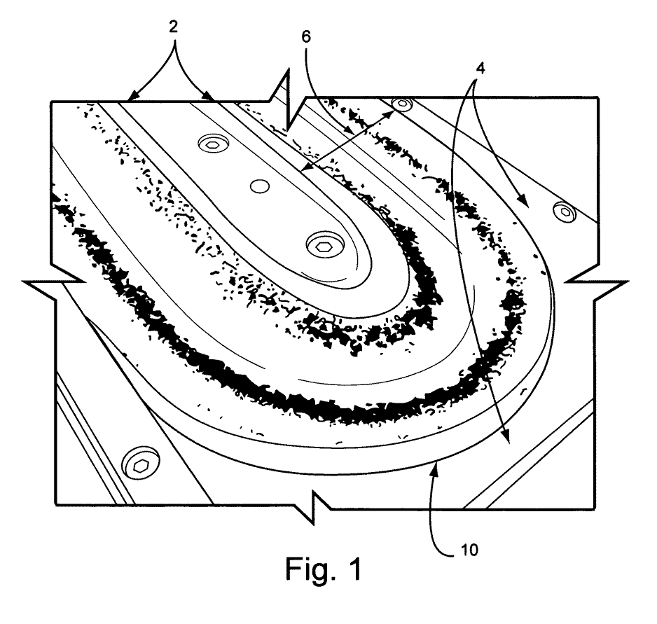

Debris will form inside and outside of this racetrack, as shown above in FIG. 1. Certain example embodiments address this problem and reduce the amount of debris from forming in the first place, e.g., through the application of a coating (e.g., a sol-gel or other coating) on areas of planar targets subject to substantially uninterrupted surface oxidation (e.g., inside or outside of the racetrack). The coating of certain example embodiments serves to encapsulate the “unused” target material (e.g., the target material inside of and external to the racetrack), thus substantially isolating these portions of the surface from the oxidizing environment. Referring to the example provided above, encapsulating a nichrome target in a way that isolates the unused portions of the target material (e.g., the target material inside of and external to the racetrack) helps reduce the amount of oxidation and the corresponding production of NiCrOx debris in such areas. Advantageously, because these areas are not used during the sputtering, target yield is substantially unaffected.

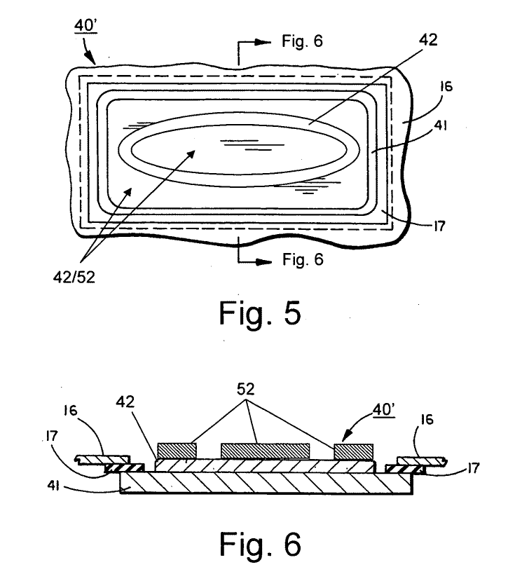

FIG. 5 is a top plan view of a planar sputtering target 40′ in accordance with an example embodiment, and FIG. 6 is a cross section of the sputtering target 40′ of FIG. 5 in accordance with an example embodiment. As can be seen from FIGS. 5 and 6, a coating 52 is applied over the target material 42 in certain portions. More particularly, coating 52 is applied over the target material 42 so as to correspond to those portions of the sputtering target 40′ that are not used in sputtering. Thus, because the sputtering target material 42 typically is used up in a manner that, when viewed from the top resembles a racetrack, the coating 52 is applied inside of and external to this racetrack. Accordingly, a racetrack of target material 42 is exposed to the inside of the sputtering apparatus 40′, whereas the rest of the target material 42 is substantially isolated from the oxidizing environment, e.g., by virtue of its location underneath the coating 52. The manner in which the sputtering target material 42 will be used may depend on, for example, the size, shape, and construction of the target including the location(s) of the cathode, magnets, etc. Thus, it will be appreciated that the shape formed by the coating may be the same as, similar to, or different from that shown in FIGS. 5 and 6.

The coating may be comprise inorganic materials or materials that resist decomposition in a severely oxidizing environment, and/or are electrically non-conductive materials. With respect to the latter, it has been determined that non-conductive materials do not sputter off at a significant rate in this DC process because they serve as insulators that substantially do not pass current. Cured form sol-gels typically comprise silicon oxide (e.g., SiO₂ or other suitable stoichiometry) and/or titanium oxide (e.g., TiO₂ or other suitable stoichiometry), and both silicon oxide and titanium oxide have been found to resist decomposition in a severely oxidizing environment and are substantially electrically non-conductive materials. Moreover, sol-gels comprising silicon oxide and/or titanium oxide may be easily applied in liquid form.

A description of how an example “sol” suitable for use in connection with certain example embodiments is now provided. A “sol” is prepared, which includes a solution or suspension in water, alcohol and/or hydroalcoholic mixtures of precursor(s) of the element(s) whose oxide(s) is/are to be prepared. For instance, precursors may be alkoxides, of formula M(OR)ₙ, where M represents the element (e.g., Si) whose oxide is desired, the group —OR is the alkoxide moiety, and “n” represents the valence of M; soluble salt(s) of M such as chlorides, nitrates, and oxides may be used in place of alkoxides in certain example embodiments. During this phase, the precursor(s) may begin to hydrolyze (with or without an acid or base catalyst), e.g., alkoxide moieties or other anion bonded to the element M(s) may be replaced by —OH groups. Sol-gelation may take from a few seconds to several days, depending on the chemical composition and temperature of the solution. During sol-gelation, hydrolysis of the possibly remaining precursor(s) may be completed or substantially completed, and condensation may occur including reaction of —OH group(s) belonging to different molecules with formation of a free water molecule and an oxygen bridge between atoms M, M′ (which may be alike or different). The product obtained in this sol-gelation phase may be called alcogel, hydrogel, xerogel, or the like, or more generally “gel” as is widely used to cover all such instances. Gel drying then occurs; in this phase, the solvent is removed by evaporation or through transformation into gas (e.g., via heating in certain instances), and a solid or dry body is obtained. Densification may be performed by heat treating or curing in certain example embodiments, whereby a porous gel densifies thereby obtaining a glassy or ceramic compact oxide.

It will be appreciated that other example “sols” may be prepared in the foregoing and/or other ways, and also may be used in connection with certain example embodiments. Furthermore, it will be appreciated that the coating mixtures suitable for use with certain example embodiments do not necessarily have to be sol-gel mixtures.

In certain example embodiments, the sol-gel coating may be applied in liquid form. In certain example embodiments, the sol-gel coating may be cured using a low temperature green cure. For example, such a cure may take place at a temperature of about 100-300 degrees C., more preferably about 125-275 degrees C., and still more preferably about 150-250 degrees C. Of course, it will be appreciated that other types of cures may be used in connection with certain example embodiments, and the other types of cures may work best with the same or different ranges of temperatures. It also will be appreciated that the type of cure may be selected at least in part on the composition of the “sol.” For example, the green cure noted above advantageously may be used in connection with liquid type sol-gels comprising silicon oxide (e.g., SiO₂ or other suitable stoichiometry).

### EXAMPLE

To test the feasibility of an oxidation barrier based on a sol-gel coating in connection with a nichrome target, the following test was devised. Three sample specimens were prepared. First, a silicon oxide inclusive sol-gel was applied in liquid form to a U.S. Mint quarter via a spray bottle. The sprayed quarter was allowed to dry, and it was green cured in a box furnace for approximately 10 minutes at about 200 degrees C. Second, a silicon oxide inclusive sol-gel was applied in liquid form to a U.S. Mint quarter via a spray bottle. This second sprayed quarter was allowed to dry, but it was not cured. Third, a U.S. Mint quarter was not treated with a sol-gel solution. As is known, U.S. Mint quarters currently have an outer cladding comprising about 25% nickel and 75% copper. An air atmosphere belt furnace was set to bake for about 30 minutes at about 625 degrees C. to simulate the harsh oxidizing environment of a sputtering apparatus.

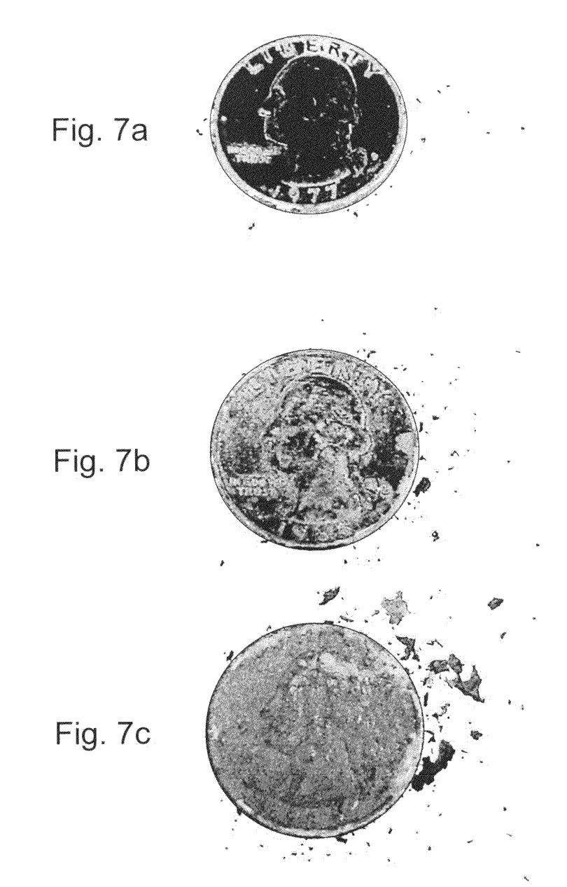

The test results for the three samples are shown in FIGS. 7a-c. As will be appreciated from these drawings, the first sample (the quarter having the wet-applied and cured sol-gel coating) showed some signs of grey material near its rim, date, and raised markings. The majority of the coin turned a dark black. Very little debris was located around the coin. The second sample (the quarter having the non-cured wet-applied sol-gel coating) formed a grey layer and also areas of dark black. The third sample (the untreated quarter) had a thick layer of grey material at its surface and was almost unrecognizable because of this grey material. It is believed that the grey material is a nickel/copper oxide.

As a further test, the surface of the three samples were scraped 10 times with a row of standard office staples. The grey layer on the untreated coin scraped off in significant amounts in the form of powder and large flakes. The grey layer on the second sample did scrape off, in part. However, the amount of debris surrounding the second sample coin was insignificant in amount and size when compared to the untreated quarter. Finally, very, very little grey material came off of the quarter having the wet-applied and cured sol-gel coating. In fact, it was almost non-existent, especially when compared to the untreated sample.

In view of the above, the encapsulating coating of certain example embodiments may reduce the amount of debris that otherwise would be formed by at least about 25%, more preferably at least about 33%, and still more preferably at least about 50%.

It will be appreciated that although the encapsulating coatings of certain example embodiments have been described as being sol-gel coatings, other techniques may be used to form the encapsulating coatings in different example embodiments of this invention. Similarly, although certain example embodiments have been described as being silicon oxide and/or titanium oxide inclusive, other materials may be used in connection with or in place of such materials. Although certain of the problems identified herein were discovered and discussed in connection with nicrhome target materials, it will be appreciated that the techniques of certain example embodiments may be used in connection with target materials other than nichrome and thus also may be useful in reducing debris other than NiCrOx formed during sputtering.

While a particular layer or coating may be said to be “on” or “supported by” a surface or another coating (directly or indirectly), other layer(s) and/or coatings may be provided therebetween. Thus, for example, a coating may be considered “on” and “supported by” a surface even if other layer(s) are provided between layer(s) and the substrate. Moreover, certain layers or coatings may be removed in certain embodiments, while others may be added in other embodiments of this invention without departing from the overall spirit of certain embodiments of this invention. Thus, by way of example, an encapsulating coating applied in liquid sol-gel form in accordance with an example embodiment may be said to be “on” or “supported by” a sputtering target material, even though other coatings and/or layers may be provided between the sol-gel formed coating and the target material.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A magnetron sputtering apparatus for sputter coating an article in a reactive environment, comprising:
a vacuum chamber;
one or more magnets arranged to facilitate the sputter coating of the article;
a sputtering target located in the vacuum chamber, the sputtering target having a target material located thereon; and
an encapsulating coating formed, directly or indirectly, on the target material at one or more first areas thereof where the target material substantially is not used in the sputter coating of the article, the encapsulating coating substantially isolating the target material at the one or more first areas from the reactive environment of the sputtering apparatus.

2. The apparatus of claim 1, wherein the sputtering target is planar.

3. The apparatus of claim 2, wherein the encapsulating coating includes inorganic materials or materials that resist decomposition in the reactive environment, and is substantially electrically non-conductive.

4. The apparatus of claim 3, wherein the encapsulating coating is a cured form sol-gel coating.

5. The apparatus of claim 4, wherein the cured form sol-gel coating includes silicon oxide and/or titanium oxide.

6. The apparatus of claim 2, wherein a cathode is connected to the planar sputtering target.

7. The apparatus of claim 2, wherein the encapsulating coating is formed on the target material such that at least some of the target material is exposed to the reactive environment, a shape of the target material exposed to the reactive environment corresponding to at least a second area thereof where the target material substantially is used in the sputter coating of the article.

8. The apparatus of claim 7, wherein the shape of the target material exposed to the reactive environment is substantially ovular or racetrack-like.

9. The apparatus of claim 1, wherein the encapsulating coating reduces an amount of debris that otherwise would be formed by oxidation of the target material in the one or more first areas by at least about 50%.

10. A method for reducing an amount of debris created during sputtering, the method comprising:
providing a magnetron sputtering apparatus configured to generate a reactive environment used in sputter coating an article, the magnetron sputtering apparatus comprising a vacuum chamber, one or more magnets arranged to facilitate the sputter coating of the article, a sputtering target having a target material located thereon and being located in the vacuum chamber; and
forming an encapsulating coating, directly or indirectly, on the target material at one or more first areas thereof where the target material substantially is not used in the sputter coating of the article, the encapsulating coating substantially isolating the target material at the one or more first areas from the reactive environment of the sputtering apparatus.

11. The method of claim 10, wherein the sputtering target is planar.

12. The method of claim 11, wherein the encapsulating coating includes inorganic materials or materials that resist decomposition in the reactive environment, and is substantially electrically non-conductive.

13. The method of claim 12, further comprising forming the encapsulating coating from a liquid sol-gel.

14. The method of claim 13, further comprising curing the liquid sol-gel.

15. The method of claim 14, wherein the curing comprises a green cure at a temperature of about 150-250 degrees C.

16. The method of claim 13, wherein the sol-gel includes silicon oxide and/or titanium oxide.

17. The method of claim 11, further comprising forming the encapsulating coating on the target material such that at least some of the target material is exposed to the reactive environment, a shape of the target material exposed to the reactive environment corresponding to at least a second area thereof where the target material substantially is used in the sputter coating of the article.

18. The method of claim 17, wherein the shape of the target material exposed to the reactive environment is substantially ovular or racetrack-like.

19. The method of claim 11, wherein the encapsulating coating reduces an amount of debris that otherwise would be formed by oxidation of the target material in the one or more first areas by at least about 50%.

20. A magnetron sputtering apparatus for sputter coating an article in an oxidizing environment, comprising:
a vacuum chamber;
one or more magnets arranged to facilitate the sputter coating of the article;
a DC planar sputtering target located in the vacuum chamber, the sputtering target having a target material located thereon;
a cathode connected to the sputtering target; and
an encapsulating coating formed, directly or indirectly, on the target material at one or more first areas thereof where the target material substantially is not used in the sputter coating of the article, the encapsulating coating substantially isolating the target material at the one or more first areas from the oxidizing environment of the sputtering apparatus,
wherein the encapsulating coating includes inorganic materials or materials that resist decomposition in the oxidizing environment, and is substantially electrically non-conductive,
wherein the encapsulating coating is formed on the target material such that at least some of the target material is exposed to the oxidizing environment in a racetrack-like shape of the target material that corresponds to at least a second area of the target material where the target material substantially is used in the sputter coating of the article, and
wherein the encapsulating coating reduces an amount of debris that otherwise would be formed by oxidation of the target material in the one or more first areas by at least about 50%.
